(19) United States
(12) Patent Application Publication
(10) Pub. No.: US 2016/0116499 A1
(43) Pub. Date: Apr. 28, 2016

(54) Apparatus for Sensor with Communication Port for Configuring Sensor Characteristics and Associated Methods

(71) Applicant: Silicon Audio Seismic, LLC, Austin, TX (US)

(72) Inventor: Charles D. Thompson, Buda, TX (US)

(21) Appl. No.: 14/520,774

(22) Filed: Oct. 22, 2014

(51) Int. Cl. G01P 21/00; B81B 3/00; B81B 7/02; G01D 5/20; G01B 11/00

(52) U.S. Cl. CPC G01P 21/00; G01D 5/20; G01B 11/00; B81B 7/02; B81B 3/0021; B81B 2201/0228

(57) ABSTRACT

A sensor includes a coil suspended in a magnetic field, an optical detector to detect displacement of the coil in response to a stimulus, and a feedback circuit coupled to the optical detector and to the coil. The sensor further includes a serial communication port used to configure at least one characteristic of the sensor, wherein the at least one characteristic of the sensor comprises an overload point of the sensor, a gain of the sensor, a full-scale range of the sensor, a power consumption of sensor, sleep mode parameters of the sensor, a coil configuration of the sensor, and/or coil damping of the sensor.

### CROSS-REFERENCE TO RELATED APPLICATIONS

This patent application is related to the following patent applications:

U.S. patent application Ser. No. ______, filed on ______, titled “Apparatus for Sensor with Programmable Gain and Dynamic Range and Associated Methods,” Attorney Docket No. SIAU002;

U.S. patent application Ser. No. ______, filed on ______, titled “Apparatus for Sensor with Configurable Coil Constant and Associated Methods,” Attorney Docket No. SIAU003;

U.S. patent application Ser. No. ______, filed on ______, titled “Apparatus for Sensor with Improved Power Consumption and Associated Methods,” Attorney Docket No. SIAU005;

U.S. patent application Ser. No. ______, filed on ______, titled “Apparatus for Sensor with Configurable Coil and Associated Methods,” Attorney Docket No. SIAU006;

U.S. patent application Ser. No. ______, filed on ______, titled “Apparatus for Sensor with Configurable Damping and Associated Methods,” Attorney Docket No. SIAU007; and

International Application No. PCT/US2013/032584, filed on Mar. 15, 2013, titled “Closed Loop Control Techniques for Displacement Sensors with Optical Readout.” The foregoing applications are incorporated by reference in their entireties for all purposes.

### TECHNICAL FIELD

The disclosure relates generally to sensors, such as acceleration, speed, and displacement sensors and, more particularly, to apparatus for such sensors with one or more communication ports that may be used for configuring various sensor parameters, and associated methods.

### BACKGROUND

With advances in electronics, a variety of sensors have been developed to sense physical quantities. The sensors may use a variety of technologies, such as electrical, mechanical, optical, and micro-electromechanical systems (MEMS), or combinations of such technologies. More particularly, some sensors can sense displacement, velocity, or acceleration. Sensors that can sense displacement, velocity, or acceleration find use in a variety of fields, such as ground or earth exploration, for instance, reflection seismology.

As an example, devices known as geophones use a magnet and a coil that move relative to each other in response to ground movement. Waves sent into the earth generate reflected energy waves. In response to reflected energy waves, geophones generate electrical signals that may be used to locate underground objects, such as natural resources.

FIG. 1 illustrates a conceptual diagram 10 of a geophone, which includes a magnet 16 coupled to an anchor point 12 (e.g., housing) and spring 14, and coil 18 with mass m. In response to a stimulus, such as the energy waves described above, coil 18 moves in relation to magnet 16. As a result, an electrical output signal is generated by coil 18.

The coil-spring assembly form a physical system that responds non-uniformly as the frequency of the stimulus is varied. Assuming that spring 14 has a spring constant k, the coil-spring assembly, with mass m (i.e., a negligible spring mass), has a natural frequency of oscillation of

$${f}_{N} = \sqrt{\frac{k}{m}} .$$

FIG. 2 illustrates a frequency response curve 20 of the geophone of FIG. 1 to physical stimuli. Frequency response curve 20 has a peak 23 at the frequency f_{N}. Thus, geophone 10 has better response (higher output signal level) at frequencies near or equal to f_{N}.

Note that the description in this section and the corresponding figures are included as background information material. The materials in this section should not be considered as an admission that such materials constitute prior art to the present patent application.

### SUMMARY

According to an exemplary embodiment, a sensor includes a coil suspended in a magnetic field, an optical detector to detect displacement of the coil in response to a stimulus, and a feedback circuit coupled to the optical detector and to the coil. The sensor further includes a serial communication port used to configure at least one characteristic of the sensor, wherein the at least one characteristic of the sensor comprises an overload point of the sensor, a gain of the sensor, a full-scale range of the sensor, a power consumption of sensor, sleep mode parameters of the sensor, a coil configuration of the sensor, and/or coil damping of the sensor.

According to another exemplary embodiment, a system includes a sensor. The sensor includes a coil suspended in a magnetic field, an optical detector to detect displacement of the coil in response to a stimulus, and a feedback circuit coupled to the optical detector and to the coil. The sensor further includes a microcontroller unit (MCU) comprising a serial communication port used to receive information to configure at least one characteristic of the sensor. The serial port is further used to provide output information of the sensor. The at least one characteristic of the sensor comprises an overload point of the sensor, a gain of the sensor, a full-scale range of the sensor, a power consumption of sensor, sleep mode parameters of the sensor, a coil configuration of the sensor, and/or coil damping of the sensor.

According to another exemplary embodiment, a method of operating a sensor is disclosed. The sensor includes a coil suspended in a magnetic field, an optical detector to detect displacement of the coil in response to a stimulus, a feedback circuit coupled to the optical detector and to the coil, and a serial communication port. The method includes using the serial communication port to configure at least one characteristic of the sensor, wherein the at least one characteristic of the sensor comprises an overload point of the sensor, a gain of the sensor, a full-scale range of the sensor, a power consumption of sensor, sleep mode parameters of the sensor, a coil configuration of the sensor, and/or coil damping of the sensor.

### BRIEF DESCRIPTION OF THE DRAWINGS

The appended drawings illustrate only exemplary embodiments and therefore should not be considered as limiting the scope of the application or the claims. Persons of ordinary skill in the art appreciate that the disclosed concepts lend themselves to other equally effective embodiments. In the drawings, the same numeral designators used in more than one drawing denote the same, similar, or equivalent functionality, components, or blocks.

FIG. 1 illustrates a conceptual diagram of a geophone.

FIG. 2 depicts the frequency response of a geophone in response to physical stimuli.

FIG. 3 shows a sensor according to an exemplary embodiment.

FIG. 4 depicts forces operating in a sensor according to an exemplary embodiment.

FIG. 5 illustrates a virtual spring caused by use of negative feedback in an exemplary embodiment.

FIG. 6 depicts a cross-section of a sensor according to an exemplary embodiment.

FIG. 7 illustrates a cross-section of a sensor according to an exemplary embodiment.

FIG. 8 shows a schematic diagram of a sensor according to an exemplary embodiment.

FIG. 9 illustrates a schematic diagram of a sensor according to an exemplary embodiment.

FIG. 10 depicts an output signal of a trans-impedance amplifier (TIA) in an exemplary embodiment.

FIG. 11 shows a flow diagram for a method of operating a sensor according to an exemplary embodiment.

FIG. 12 illustrates a block diagram of a sensor communicating with another device or component according to an exemplary embodiment.

FIG. 13 depicts a circuit arrangement for using a communication port in a sensor according to an exemplary embodiment.

FIG. 14 illustrates a circuit arrangement for using a communication port in a sensor according to another exemplary embodiment.

FIG. 15 shows a circuit arrangement for using a communication port in a sensor according to another exemplary embodiment.

FIG. 16 depicts a circuit arrangement for configuring one or more sensor characteristics according to an exemplary embodiment.

FIG. 17 depicts a circuit arrangement for configuring one or more sensor characteristics according to another exemplary embodiment.

FIG. 18 depicts a feedback network for configuring one or more sensor characteristics according to an exemplary embodiment.

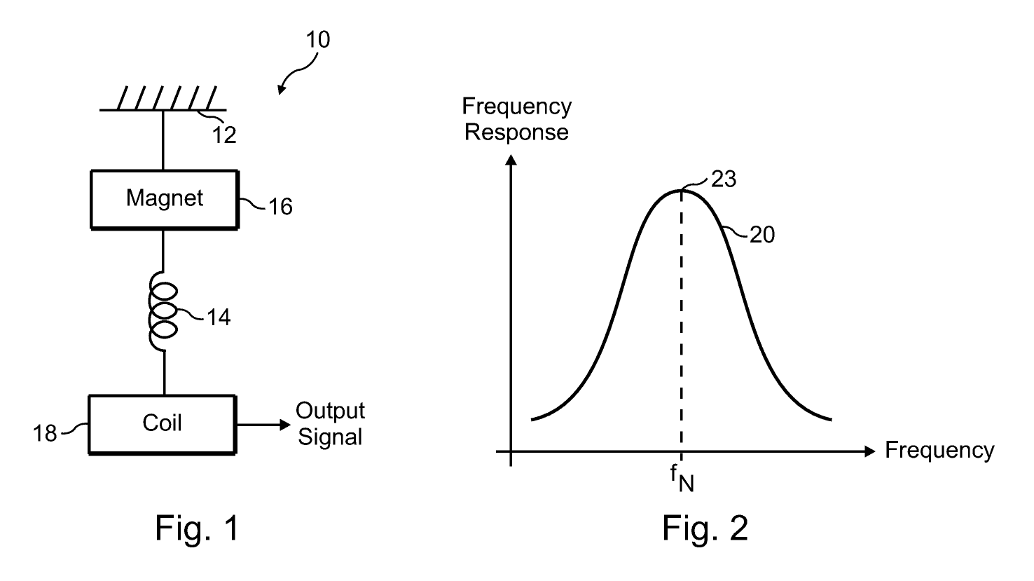

### DETAILED DESCRIPTION

The disclosed concepts relate generally to sensors, such as acceleration, speed, and displacement sensors. More specifically, the disclosed concepts provide systems, apparatus, and methods for sensors with apparatus for such sensors with one or more communication ports. The communication ports may be used for programming various sensor parameters, as described below in detail.

Sensors according to exemplary embodiments can sense acceleration, velocity, and/or displacement. As persons of ordinary skill in the art understand, acceleration, velocity, and displacement are governed by mathematical relationships. Thus, one may sense one of acceleration, velocity, and displacement, and derive the others from it.

For example, if acceleration, a, is sensed, velocity, v, and displacement, x, may be derived from a. More specifically:

$$a = \frac{d v}{d t} ⇒ v = \int a \cdot d t$$

$$v = \frac{d x}{d t} ⇒ x = \int v \cdot d t$$

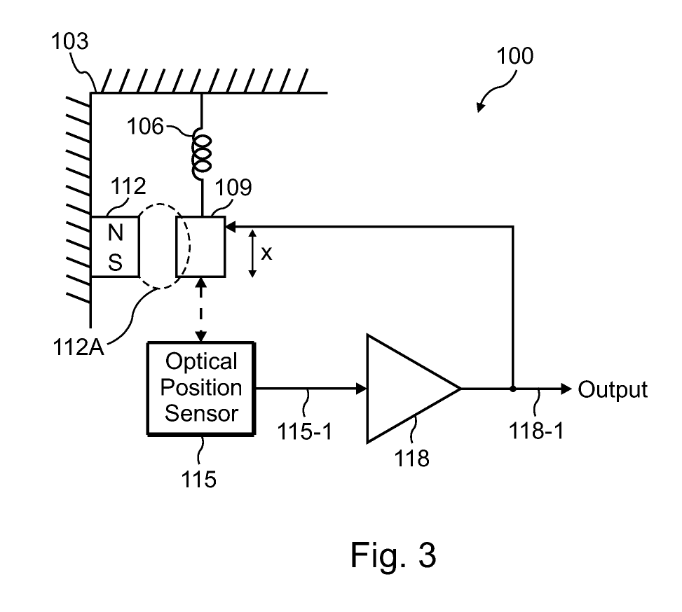

Sensors according to exemplary embodiments include a combination of electrical, optical, and mechanical components. FIG. 3 illustrates a conceptual diagram of a sensor 100 according to an exemplary embodiment.

Referring to FIG. 3, sensor 100 includes a spring 106 attached (e.g., at one end) to an acceleration reference frame or plane 103. Spring 106 has a spring constant kₛ. Spring 106 is also attached (e.g., at another end) to coil 109. Coil 109 and its corresponding assembly (not shown), e.g., a bobbin, have a mass m, also known as proof mass.

A magnet 112 is positioned near or proximately to coil 109. A magnetic field 112A is established between the north and south poles of magnet 112. Thus, coil 109 is completely or partially suspended within magnetic field 112A. By virtue of spring 106, coil 109 may move in relation to magnet 112 and, thus, in relation to magnetic field 112A.

More specifically, in response to a physical stimuli, such as a force that causes displacement x of coil 109, coil 109 moves in relation to magnet 112 and magnetic field 112A. As persons of ordinary skill in the art understand, movement of a conductor, such as coil 109, in a magnetic field, such as magnetic field 112A, induces a current in the coil. Thus, in response to the stimuli, coil 109 produces a current.

Optical position sensor 115 detects the movement of coil 109 in response to the stimuli. More specifically, as described below in detail, optical position sensor 115 generates an output signal, for example, a current, in response to the movement of coil 109.

Note that in some embodiments, rather than generating a current, optical position sensor 115 may generate a voltage signal. For example, optical position sensor 115 may include a mechanism, such as an amplifier or converter, to convert a current produced by the electro-optical components of optical position sensor 115 to an output voltage. In either case, optical position sensor 115 provides an output signal 115-1 to amplifier 118.

Without loss of generality, in exemplary embodiments, amplifier 118 constitutes a TIA. TIA 118 generates an output voltage in response to an input current. Thus, in the case where optical position sensor 115 provides an output current (rather than an output voltage) 115-1, TIA 118 converts the current to a voltage signal.

In some embodiments, depending on a number of factors, TIA 118 may include circuitry for driving coil 109, such as a coil driver (not shown). Such factors include design and performance specifications for a given implementation, for example, the amount of drive specified for coil 109, etc., as persons of ordinary skill in the art will understand.

TIA 118 (or other amplifier circuitry, as noted above) provides an output signal 118-1 to coil 109. The polarity of output signal 118-1 is selected such that output signal 118-1 counteracts the current induced in coil 109 in response to the physical stimuli. In other words, optical position sensor 115 and TIA 118 couple to coil 109 so as to form a negative-feedback loop.

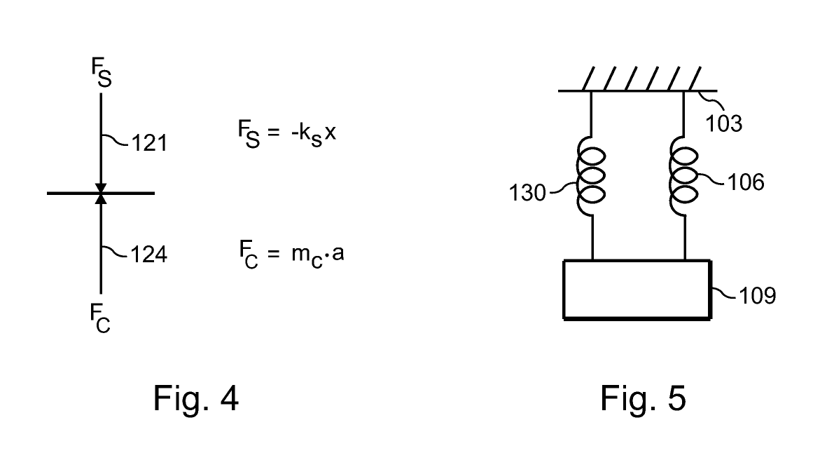

The feedback or driving signal, i.e., signal 118-1, causes a force to act on coil 109. In exemplary embodiments, the force is proportional to the displacement x. Thus, a force exerted by spring 106 and a force exerted by coil 109 (by virtue of negative feedback and driving signal 118-1) cooperate with each other against the force created by acceleration of coil 109 (the proof mass). FIG. 4 illustrates the two forces.

More specifically, FIG. 4 shows a force vector 121 that corresponds to force Fₛ exerted by spring 106. FIG. 4 also depicts a force vector 124 that corresponds to force F_{c} exerted by virtue of the acceleration of coil 109. According to Hook's law, force Fₛ relates to displacement x, specifically Fₛ=−kₛ·x, where, as noted above, kₛ represents the spring constant of spring 106. In effect, spring 106 resists the displacement in proportion to kₛ.

Furthermore, according to Newton's second law (ignoring any relativistic effects), force F_{c} relates to the mass of coil 109 (including any physical components, such as a bobbin), and to the acceleration that coil 109 experiences as a result of the external stimuli (e.g., the source that causes displacement x to occur). Specifically, F_{c}=m_{c}·a, where m_{c} represents the mass of coil 109, and a denotes the acceleration that coil 109 experiences.

As noted above, negative feedback is employed in sensor 100 (see FIG. 5) so as to cause the mass m_{c} to come to equilibrium. Mathematically stated, the feedback causes the mass m_{c} to come to equilibrium when Fₛ equals F_{c}. Thus, sensor 100 may be viewed as operating according to a force-balance principle, i.e., Fₛ=F_{c} at equilibrium.

Stated another way, force-balance occurs when −kₛ·x=m_{c}·a. One may readily determine the spring constant kₛ and the mass of coil 109, m_{c} (e.g., by consulting data sheets or controlling manufacturing processes, etc.). Using the values of kₛ and m_{c} in the above equation, one may determine the acceleration of coil 109 in response to the stimulus, i.e.:

$$a = \frac{- {k}_{s} \cdot x}{{m}_{c}} .$$

In other words, output signal 118-1 of TIA 118 is proportional to acceleration a. Given acceleration a, velocity v, and displacement x may be determined, by using the mathematical relations described above. (Note also that optical position sensor 115 may also determine displacement x). Thus, sensor 100 may be used to determine displacement (position), velocity, and/or acceleration, as desired.

Using negative feedback provides a number of benefits. First, it flattens or tends to flatten the response of sensor 100 to the stimuli. Second, feedback increases the frequency response of sensor 100, i.e., sensor 100 has more of a broadband response because of the use of feedback.

Third, negative feedback reduces the amount of displacement that results in a desired output signal level. In effect, negative feedback acts as a virtual spring coupled in parallel with spring 106, a concept that FIG. 5 illustrates. More specifically, the negative-feedback signal applied to coil 109 causes virtual spring 130 to counteract force F_{c}, which is exerted because of the acceleration of coil 109, as described above. Thus, spring 106 and virtual spring 130 work as additive forces to reach force equilibrium in opposition to the force created by acceleration of the coil mass (proof mass). Virtual spring 130 is controlled electronically, e.g., by TIA 118 in FIG. 3.

Referring again to FIG. 5, because of the use of negative feedback, virtual spring 130 has a larger spring constant, kᵥ, than does spring 106. Use of virtual spring 130 results in sensor 100 creating a given output in response to a smaller stimulus. Put another way, virtual spring 130 acts as a stiff spring. Thus, compared to an open-loop arrangement, sensor 100 has a reduced total displacement for a desired level of output signal. Also, force applied to a sensor that uses an open-loop arrangement (e.g., a geophone), causes the mass suspended by the spring to wobble more, which limits the upper response limit of the sensor.

As noted, use of negative feedback flattens or tends to flatten the sensor frequency response, and also reduces the sensitivity of the force-balance system to the value of spring constant kₛ of spring 106, since the spring constant of virtual spring 130 dominates. A benefit of the foregoing is to allow the use of a stiffer spring suspension 106, which in turn facilitates sensor operation at any orientation with respect to Earth's gravity. Additionally, an increase in loop gain results in a stiffer virtual spring constant 130, which in turn allows a larger full scale stimulus range.

Note that a variety of embodiments of sensors according to the disclosure are contemplated. For example, in some embodiments, the position of coil 109 and magnet 112 may be reversed or switched (see FIG. 3). Thus, coil 109 may be stationary, while magnet 112 may be suspended by spring 106.

As another example, in some embodiments, more than one magnet 112 may be used, as desired. As yet another example, in some embodiments, more than one coil 109 may be used, e.g., two coils in parallel or series, as desired. Other arrangements are possible, depending on factors such as design and performance specifications, cost, available technology, etc., as persons of ordinary skill in the art will understand.

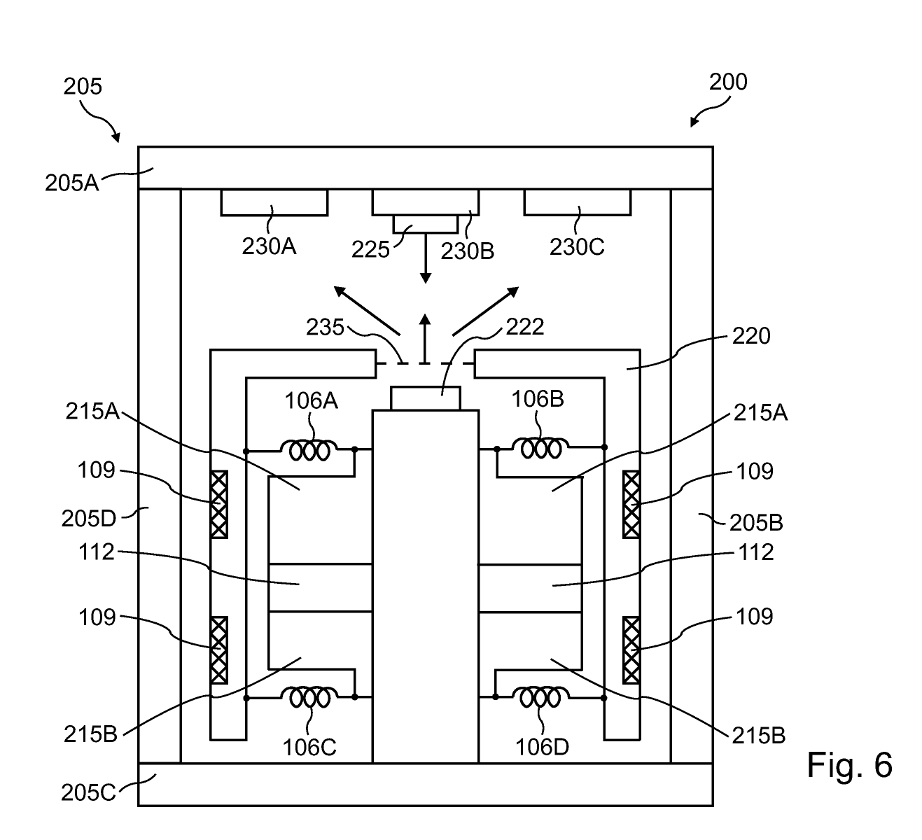

FIG. 6 depicts a cross-section of a sensor 200 according to an exemplary embodiment. Sensor 200 includes a housing, frame, or enclosure 205 to provide physical support for various components of sensor 200. In the embodiment shown, housing 205 has sides 205A, 205B, 205C, and 205D, for example, a top, a right side or wall, a bottom, and a left side or wall. Other housing, frames, or enclosures are possible and contemplated, as persons of ordinary skill in the art will understand.

Magnet 112 is arranged with magnet caps 215A and 215B. In the embodiment shown, magnet 112 is disposed between magnet caps 215A and 215B. A variety of types and shapes of magnets may be used, as desired. Examples include neodymium-iron-boron (NIB) or aluminum nickel cobalt (ALNICO) alloy magnets, but other materials, such as alloys with appropriate properties, may be used. Other arrangements of the magnet and magnet caps or support are possible and contemplated, as persons of ordinary skill in the art will understand.

Coil 109 is wound on a bobbin 220. In the embodiment shown, coil 109 and bobbin 220 together form the proof mass (neglecting the mass of spring 106). In the embodiment shown, coil 109 is wound in two sections on bobbin 220, although other arrangements are possible and contemplated, as persons of ordinary skill in the art will understand.

The proof mass is suspended by spring 106, which for illustration purposes is shown as four sections labeled 106A-106D. In exemplary embodiments, spring 106 may include one, two, or more springs, such as flat, leaf, or spider springs, as desired. Other types and/or arrangements of spring 106 are possible and contemplated, as persons of ordinary skill in the art will understand. A variety of materials and techniques may be used to fabricate spring 106. Some examples include etching or die cutting. Beryllium copper may be used as one example of spring material, but other materials with appropriate spring properties (e.g., having relatively low temperature coefficient) may be used, as desired.

In exemplary embodiments, such as the embodiment of FIG. 6, spring 106 may have a relatively low spring constant. More specifically, spring 106 may have sufficient stiffness to suspend and support the proof mass. As noted above, a virtual spring (not shown) having a relatively high spring constant (i.e., higher than the spring constant of spring 106) operates in conjunction with spring 106. Thus, spring 106 may provide just enough stiffness to physically support the proof mass.

In the embodiment shown in FIG. 6, spring 106 (shown as sections or portions 106A-106D) suspend the proof mass with respect to magnet 112 (and magnet caps 215A-215B, if used). In other words, a stimulus, such as force, applied to sensor 200 causes the proof mass to move or experience a displacement with respect to magnet 112 (and magnet caps 215A-215B). Other arrangements are possible and contemplated, as persons of ordinary skill in the art will understand. For example, spring 106 may attach to housing 205, rather than magnet caps 215A-215B.

Sensor 200 includes an optical interferometer to generate an electrical signal in response to displacement of coil 109 in relation to magnet 112 or housing 205. The electrical signal constitutes the output of the optical interferometer. The electrical signal may be provided to an amplifier, e.g., TIA 118 in FIG. 3.

Referring again to FIG. 6, in the embodiment shown, the optical interferometer includes a light source 225, such as a vertical cavity surface-emitting laser (VCSEL). The light output of light source 225 is reflected by a mirror 222, and is diffracted by diffraction grating 235. The resulting optical signals are detected by optical detectors 230A, 230B, and 230C.

A mechanical or physical stimulus applied to sensor 200 causes a change in the detected light, and thus causes optical detectors 230A-230C to provide an electrical output signal. The electrical output signal, e.g., a current signal, may be used in a feedback loop, as discussed above.

Note that, if desired, the electrical output signal may be used in an open-loop configuration, rather than in a closed-loop (negative feedback) configuration. As noted above, closed-loop configuration provides some advantages over open-loop configuration. In some situations, however, operating sensor 200 in an open-loop configuration may be desired, for instance, on a temporary basis.

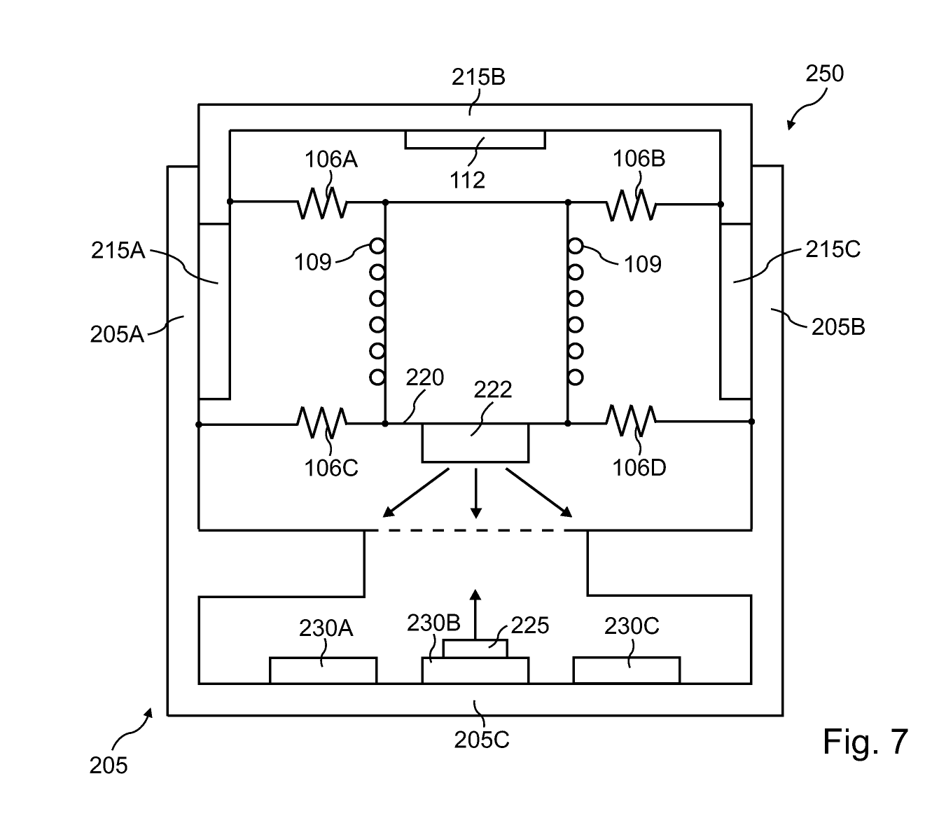

FIG. 7 depicts a cross-section of a sensor 250 according to an exemplary embodiment. Sensor 250 includes a housing, frame, or enclosure 205 to provide physical support for various components of sensor 250. In the embodiment shown, housing 205 has sides 205A, 205B and 205C, for example, a right side or wall, a bottom, and a left side or wall. Other housing, frames, or enclosures are possible and contemplated, as persons of ordinary skill in the art will understand.

Magnet 112 is arranged with magnet caps 215A, 215B, and 215C. In the embodiment shown, magnet 112 is attached to magnet cap 215B, which is disposed against or in contact with magnet caps 215A and 215C. A variety of types and shapes of magnets may be used, as desired. As noted, examples include neodymium-iron-boron (NIB) or aluminum nickel cobalt (ALNICO) alloy magnets, but other materials, such as alloys, with appropriate properties can be used. In some embodiments, magnet 112 may extend to a cavity in bobbin 220 (described below). Other arrangements of the magnet and magnet caps or support are possible and contemplated, as persons of ordinary skill in the art will understand.

Coil 109 is wound on a bobbin 220. In the embodiment shown, coil 109 and bobbin 220 together form the proof mass (neglecting the mass of spring 106). In the embodiment shown, coil 109 is wound around bobbin 220, although other arrangements are possible and contemplated, as persons of ordinary skill in the art will understand.

The proof mass is suspended by spring 106, which for illustration purposes is shown as four sections labeled 106A-106D. In exemplary embodiments, spring 106 may include one, two, or more springs, such as flat, leaf, or spider springs, as desired. Other types and/or arrangements of spring 106 are possible and contemplated, as persons of ordinary skill in the art will understand. As noted above, a variety of materials and techniques may be used to fabricate spring 106. Some examples include etching or die cutting. Beryllium copper may be used as one example of spring material, but other materials with appropriate spring properties (e.g., having relatively low temperature coefficient) may be used, as desired.

In exemplary embodiments, such as the embodiment of FIG. 7, spring 106 may have a relatively low spring constant. More specifically, spring 106 may have sufficient stiffness to suspend and support the proof mass. As noted above, a virtual spring (not shown), having a relatively high spring constant (i.e., higher than the spring constant of spring 106) operates in conjunction with spring 106. Thus, spring 106 may provide just enough stiffness to physically support the proof mass.

In the embodiment shown in FIG. 7, spring 106 (shown as sections or portions 106A-106D) suspend the proof mass with respect to magnet 112 (and magnet caps 215A-215C, if used). In other words, a stimulus, such as force, applied to sensor 250 causes the proof mass to move or experience a displacement with respect to magnet 112 (and magnet caps 215A-215C). Other arrangements are possible and contemplated, as persons of ordinary skill in the art will understand. For example, spring 106 may attach to magnet caps 215A and 215C, rather than housing 205.

Sensor 250 includes an optical interferometer to generate an electrical signal in response to displacement of coil 109 in relation to magnet 112 or housing 205. The electrical signal constitutes the output of the optical interferometer. The electrical signal may be provided to an amplifier, e.g., TIA 118 in FIG. 3.

Referring again to FIG. 7, in the embodiment shown, the optical interferometer includes a light source 225, such as a VCSEL. The light output of light source 225 is reflected by a mirror 222, and is diffracted by diffraction grating 235. The resulting optical signals are detected by optical detectors 230A, 230B, and 230C.

A stimulus applied to sensor 250 causes a change in the detected light, and thus causes optical detectors 230A-230C to provide an electrical output signal. The electrical output signal, e.g., a current signal, may be used in a feedback loop, as discussed above.

Note that, if desired, the electrical output signal may be used in an open-loop configuration, rather than in a closed-loop (negative feedback) configuration. As noted above, closed-loop configuration provides some advantages over open-loop configuration. In some situations, however, operating sensor 250 in an open-loop configuration may be desired, for instance, on a temporary basis.

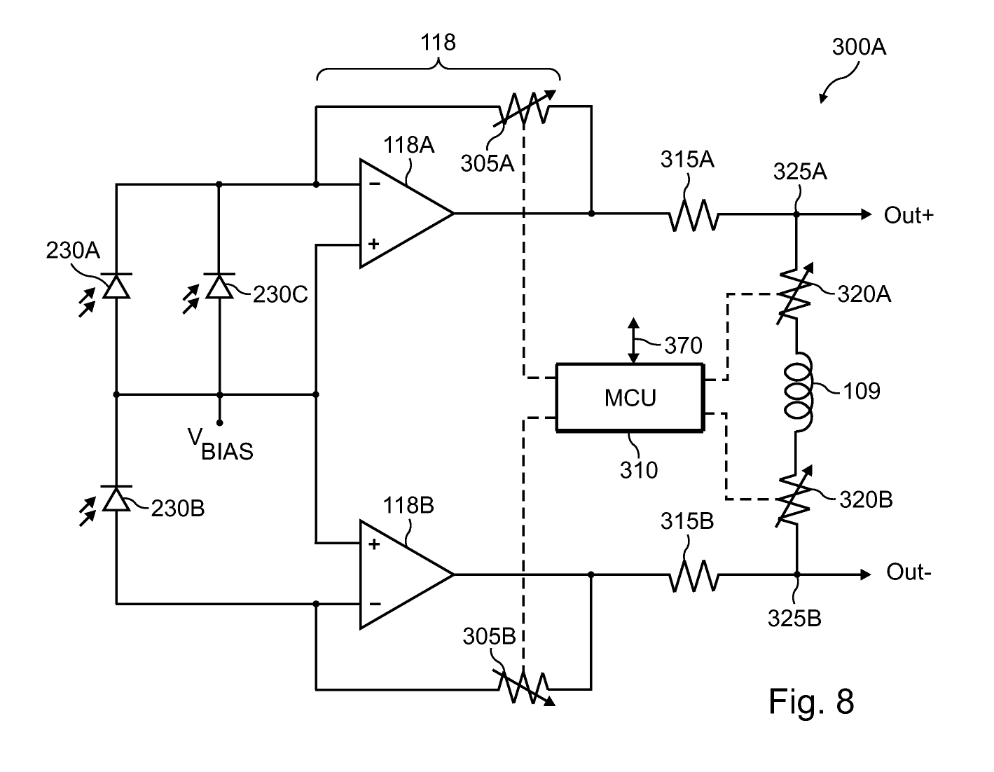

FIG. 8 shows a schematic diagram or circuit arrangement 300A for a sensor according to an exemplary embodiment, for instance sensors 200 and 250 in FIGS. 6 and 7, respectively. Referring to FIG. 8, as described above, optical detectors 230A-230C (photodiodes in the embodiment shown) provide an output signal to TIA 118. A bias source, labeled V_{BIAS}, for example, ground or zero potential, provides an appropriate bias signal to detectors 230A-230C. In the embodiment of FIG. 8, the output signal of optical detectors 230A-230C is provided to TIA 118 as a differential signal.

Note that FIG. 8 omits light source 225 for the sake of clarity of presentation. Light source 225, e.g., a VCSEL, may be powered by an appropriate circuit (not shown). Examples include a voltage regulator, a reference source, etc., as desired. Also, in some embodiments, MCU 310 may control or program the light level that light source 225 emits, depending on various factors, such as power consumption, desired sensor parameters and performance, etc.

In the embodiment shown in FIG. 8, TIA 118 includes two individual TIA circuits or amplifiers, 118A and 118B, to accommodate the differential input signal. TIA 118 includes resistors 305A-305B to adjust (or calibrate or set or program or configure) the gain of TIAs 118A-118B, respectively.

Thus, by adjusting resistor 305A, the gain of amplifier 118A may be adjusted. Similarly, by adjusting resistor 305B, the gain of amplifier 118B may be adjusted. A controller, such as a microcontroller unit (MCU) 310 in the exemplary embodiment shown, adjusts the values of resistors 305A-305B.

Typically, given the differential nature of the input signal of TIA 118, MCU 310 adjusts resistors 305A-305B to the same resistance value so as to increase or improve the common-mode rejection ration (CMRR) of TIA 118. Put another way, the two branches of TIA 118, i.e., the branches containing amplifiers 118A and 118B, respectively, are typically matched by adjusting resistors 305A-305B to the same resistance value. In some situations, however, resistors 305A-305B might be adjusted to different values, for example to compensate for component mismatch, manufacturing variations, etc.

Note that adjusting the gains of amplifiers 118A-118B does not set the full-scale range of the sensor. Rather, the gains of amplifiers 118A-118B determine the overload point of the sensor, i.e., the peak overload point of the sensor in response to a stimulus. Furthermore, the coil constant of coil 109 determines the magnitude of the output signal of the sensor in response to a given amount of acceleration in response to a stimulus, such as force. The coil constant is defined in units of Newtons per Ampere. Increasing the coil constant increases the full-scale range of the sensor for a given available or applied coil current. For fixed values of resistors 320A and 320B, the effect of increasing coil constant is a decrease in the sensor's scale factor in terms of Volts per unit of stimulus (e.g., acceleration (g)), as force-balance equilibrium will be reached at a lower coil current (and hence output voltage) for a given stimulus value.

The output of amplifier 118A feeds one end or terminal of coil 109 via resistors 315A and 320A. Conversely, the output of amplifier 118B feeds the other end of coil 109 via resistors 315B and 320B. Thus, amplifiers 118A-118B provide a drive signal for coil 109 via resistors 315A-315B and 320A-320B.

MCU 310 may adjust (or calibrate or set or program or configure) the values of resistors 320A-320B. Similar to resistors 305A-305B, typically, given the differential nature of the output signal of the sensor, MCU 310 adjusts resistors 320A-320B to the same resistance value. In some situations, however, resistors 320A-320B might be adjusted to different values, for example to compensate for component mismatch, manufacturing variations, etc.

Note that the values of resistors 320A-320B affect the gain or scale factor of the sensor. In other words, the values of resistors 320A-320B determine the full range or scale that the sensor can sense, e.g., the full range of acceleration in response to the stimulus.

Nodes 325A and 325B provide the differential output signal of the sensor. In the embodiment shown, node 325A provides the positive output signal, whereas node 325B provides the negative output signal. Together, the positive and negative output signals provide a differential output signal that is proportional to acceleration, a, experienced by the proof mass in response to the stimulus (e.g., force), as discussed above.

In some embodiments, MCU 310 may include circuitry to receive and process the output signal provided at nodes 325A-325B. For example, MCU 310 may include analog-to-digital converter (ADC) circuitry to convert the output signal at nodes 325A-325B to a digital quantity. MCU 310 may communicate the resulting digital quantity to another circuit or component, for example, via link 370, as desired. Furthermore, MCU 310 may receive power (to supply the various components in the sensor) or other information, for example, parameters related to adjusting various resistor values, as described above, via link 370.

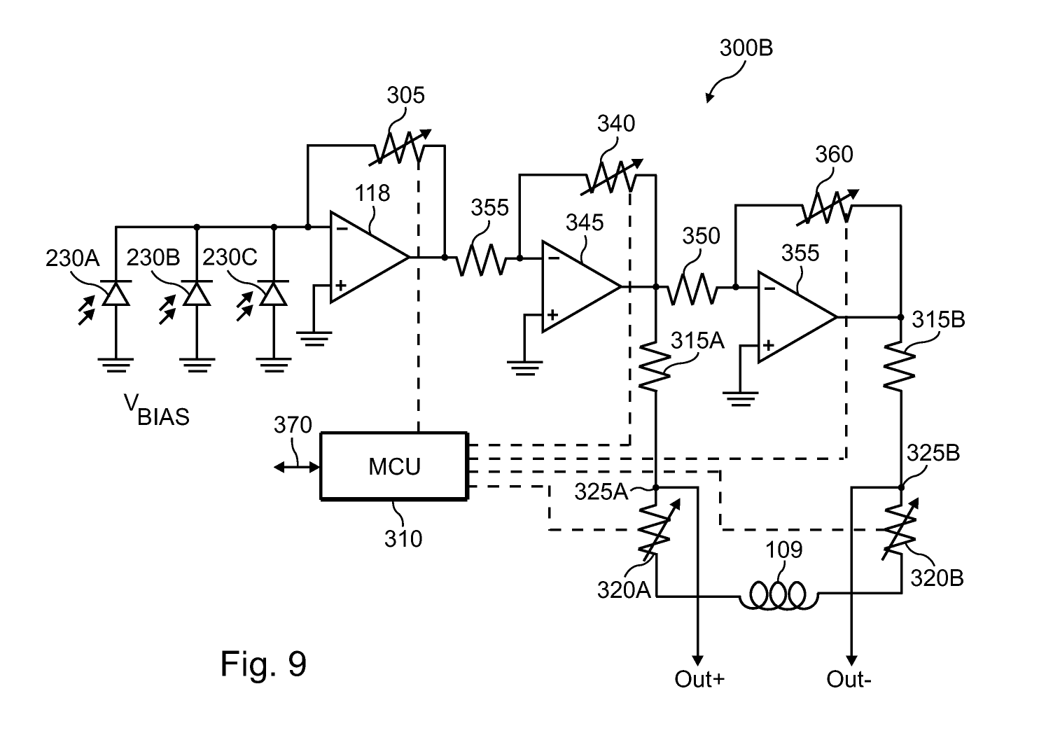

FIG. 9 shows a schematic diagram or circuit arrangement 300B for a sensor according to an exemplary embodiment, for instance sensors 200 and 250 in FIGS. 6 and 7, respectively. Referring to FIG. 9, as described above, optical detectors 230A-230C (photodiodes in the embodiment shown) provide an output signal to TIA 118. In the example shown, V_{BIAS} is ground potential although, as noted above, other appropriate values may be used. In the embodiment of FIG. 9, the output signal of optical detectors 230A-230C is provided to TIA 118 as a single-ended signal.

Note that FIG. 9 omits light source 225 for the sake of clarity of presentation. Light source 225, e.g., a VCSEL, may be powered by an appropriate circuit (not shown). Examples include a voltage regulator, a reference source, etc., as desired. Also, in some embodiments, MCU 310 may control or program the light level that light source 225 emits, depending on various factors, such as power consumption, desired sensor parameters and performance, etc.

The gain of TIA 118 may be adjusted by adjusting (or calibrating or setting or programming or configuring) resistor 305. In the embodiment shown, MCU 310 adjusts the values of resistor 305. In other embodiments, other arrangements may be used, as desired, for example, use of a host or controller coupled to the sensor, described below.

The output of TIA 118 drives an input of amplifier 345 via resistor 335. A feedback resistor 340 couples the output of amplifier 345 to resistor 335 (input of amplifier 345). If desired, the gain of amplifier 345 may be adjusted by adjusting resistor 340 (more specifically, the ratio of resistors 340 and 335). In the embodiment shown, MCU 310 may adjust the value of resistor 345.

The output of amplifier 345 drives an input of amplifier 355 via resistor 350. A feedback resistor 360 couples the output of amplifier 355 to resistor 350 (input of amplifier 355). If desired, the gain of amplifier 355 may be adjusted by adjusting resistor 360 (more specifically, the ratio of resistors 360 and 350). In the embodiment shown, MCU 310 may adjust the value of resistor 360.

Note that adjusting the gain of TIA 118 (and optionally the gains of amplifiers 345 and 355) does not set the full-scale range of the sensor. Rather, the gain of TIA 118 (and optionally the gains of amplifiers 345 and 355) determines the overload point of the sensor, i.e., the peak overload point of the sensor in response to a stimulus. Furthermore, the coil constant of coil 109 determines the magnitude of the output signal of the sensor in response to a given amount of acceleration in response to a stimulus, such as force. More specifically, the coil constant of coil 109 in conjunction with the values of 320A and 320B determine the output scale factor in Volts per unit of stimulus, e.g., g of acceleration.

The output of amplifier 345 feeds one end or terminal of coil 109 via resistors 315A and 320A. Conversely, the output of amplifier 355 feeds the other end of coil 109 via resistors 315B and 320B. Thus, amplifiers 345 and 355 provide a drive signal for coil 109 via resistors 315A-315B and 320A-320B.

MCU 310 may adjust (or calibrate or set or program or configure) the values of resistors 320A-320B. Note that the values of resistors 320A-320B affect the gain or scale factor of the sensor. In other words, the values of resistors 320A-320B determine the full range or scale that the sensor can sense, e.g., the full range of acceleration in response to the stimulus.

Nodes 325A and 325B provide the differential output signal of the sensor. In the embodiment shown, node 325A provides the positive output signal, whereas node 325B provides the negative output signal. Together, the positive and negative output signals provide a differential output signal that is proportional to acceleration, a, experienced by the proof mass in response to the stimulus (e.g., force), as discussed above.

In some embodiments, MCU 310 may include circuitry to receive and process the output signal provided at nodes 325A-325B. For example, MCU 310 may include analog-to-digital converter (ADC) circuitry to convert the output signal at nodes 325A-325B to a digital quantity. MCU 310 may communicate the resulting digital quantity to another circuit or component, for example, via link 370, as desired. Furthermore, MCU 310 may receive power (to supply the various components in the sensor) or other information, for example, parameters related to adjusting various resistor values, as described above, via link 370.

Note that although the exemplary embodiments of FIGS. 8-9 show MCU 310 as the controller, other possibilities exist and are contemplated. For example, a processor (e.g., a central processing unit (CPU) or other type of processor), a logic circuit, a finite-state machine, etc., may be used to control the values of the various resistors. The choice of the controller used depends on factors such as design and performance specifications, the degree of flexibility and programmability desired, the available technology, cost, etc., as persons of ordinary skill in the art will understand.

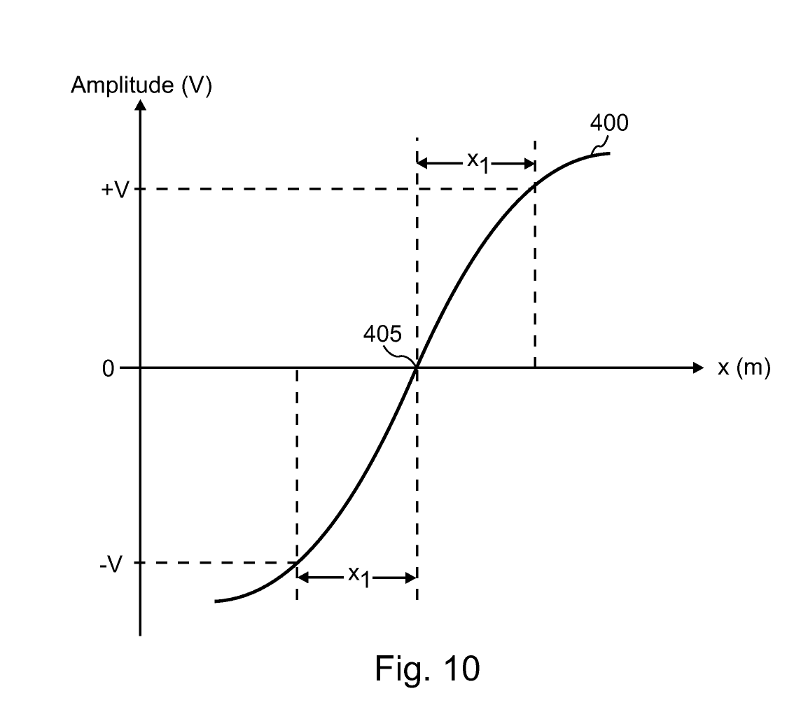

FIG. 10 illustrates the output signal 400 of a TIA 118 in an exemplary embodiment, for example, one of the embodiments of FIGS. 3 and 6-9. Output signal 400 shows how the output signal 400 (measured in Volts) of TIA 118 varies as a function of displacement, x (measured in meters). The output signal 400 shows a variation around a reference point 405 in response to displacement.

Thus, in the example shown, in response to a displacement x₁, having, for example, an absolute value of 100 nm around reference point 405 (say, ±100 nm), the output signal 400 varies from −V to +V, for example, by ±2 volts. The output signal 400 is a function of the gain of TIA 118. As noted above, the gain of TIA 118 determines the peak response or overload point of TIA 118.

Note that the output signal 400 of TIA 118 may be periodic (e.g., a cyclical interference fringe condition) in response to displacement, as persons of ordinary skill in the art will understand. FIG. 10 shows merely a portion of output signal 400 for the sake of discussion.

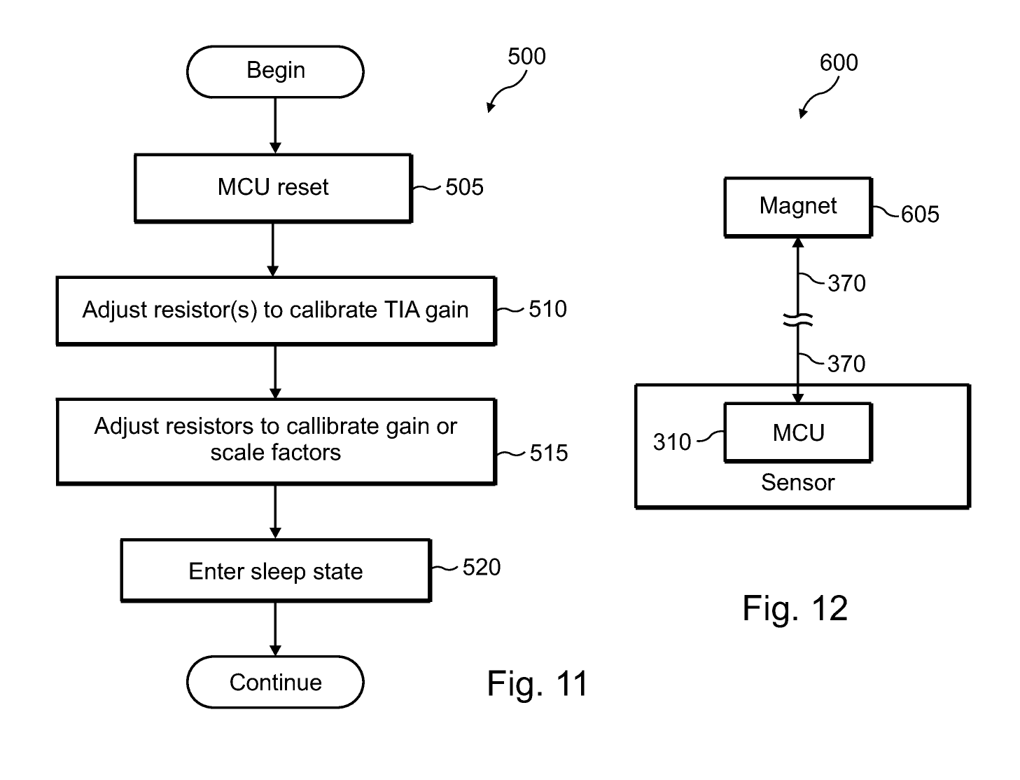

FIG. 11 shows a flow diagram 500 for a method of operating a sensor according to an exemplary embodiment. More specifically, the figure illustrates the actions that a controller, such as MCU 310, described above, may take, starting with the sensor's power-up.

After power-up, at 505 MCU 310 is reset. The reset of MCU 310 may be accomplished in a variety of ways. For example, a resistor-capacitor combination may hold the reset input of MCU 310 for a sufficiently long time to reset MCU 310. As another example, a power-on reset circuit external to MCU 310 may cause MCU 310 to reset. As another example, MCU 310 may be reset according to commands or control signals from a host.

After reset, MCU 310 begins executing firmware or user program instructions. The firmware or user program instructions may be included in a storage circuit within MCU 310 (e.g., internal flash memory) or in a storage circuit external to MCU 310 (e.g., an external flash memory). In any event, MCU 310 takes various actions in response to the firmware or user program instructions.

At 510, MCU 310 adjusts one or more resistors (e.g., resistors 305A-305B in FIG. 8 or resistor 305 in FIG. 9) to calibrate the gain of TIA 118 (see, for example, FIGS. 8 and 9). As described above in detail, the gain of TIA 118 affects certain attributes of the sensor.

At 515, MCU 310 adjusts resistors (e.g., resistors 320A-320B in FIGS. 8 and 9) in the signal path that drives coil 109 (see, for example, FIGS. 8 and 9). As described above in detail, the values of resistors 320A-320B affects certain attributes of the sensor, such as gain or scale of the sensor. Optionally, MCU 310 may make other adjustments or calibrations, for example, it may adjust the values of resistors 340 and 360 (see FIG. 9).

Referring again to FIG. 11, at 520 MCU 310 may optionally enter a sleep state. In the sleep state certain parts or blocks of MCU 310 may be disabled or powered down or placed in a low-power state (compared to when MCU 310 is powered up). Examples include placing the processor, input/output (I/O) circuits, signal processing circuits (e.g., ADC), and/or other circuits (e.g., arithmetic processing circuits) of MCU 310 in a sleep state.

Placing some of the circuitry of MCU 310 in a sleep state lowers the power consumption of MCU 310, in particular, and of the sensor, overall. Depending on the amount of power consumed in the sleep state and factors such as power-source capacity (e.g., the capacity of a battery used to power the sensor), MCU 310 may remain in the sleep state for relatively long periods of time, e.g., days, weeks, months, or even longer. Thus, the power savings because of the use of the sleep state provide a particular benefit in portable or remote applications where a battery may be used to power the sensor.

Note that some circuitry in MCU 310 may be kept powered up, even during the sleep mode or state. For example, a real-time clock (RTC) circuit (or other timer circuitry) may be kept powered and operational so as to track the passage of time. As another example, interrupt circuitry of MCU 310 may be kept powered and operation so that MCU 310 may respond to interrupts.

As part of entering the sleep state, the state of MCU 310 may be saved, for example, contents of registers, content of the program counter, etc. Saving the state of MCU 310 allows restoring MCU 310 later (e.g., when MCU 310 wakes up or resumes from the sleep state) to the same state as when it entered the sleep state.

MCU 310 may leave the sleep mode or state (wake up) and enter the normal mode of operation (e.g., processing signals generated in the sensor in response to a stimulus), or resume from the sleep state. For instance, in some embodiments, MCU 310 (or a CPU or other processor or controller) remains in the sleep state until one or more conditions are met, for example, the output signal (Out+-Out−) exceeding a preset threshold or value, or a timer generating a signal after a preset amount of time has elapsed, etc. In some embodiments, once the condition(s) is/are met, an interrupt may be generated to cause MCU 310 to leave the sleep state.

As part of the process of leaving the sleep state and entering the normal mode of operation, the state of MCU 310 may be restored (if the state was saved, as described above). Once MCU 310 leaves the sleep state, it can process signals generated in response to the stimuli, as described above.

In some embodiments, the sensor may be self-contained. In other words, the sensor, e.g., MCU 310, may include instructions for code that determine how the sensor responds to stimuli, how it processes the signals generated as a result of the application of the stimulus (e.g., log the signal values, and time/date information, as desired), etc. The sensor may also include a source of energy, such as a battery, to supply power to the various circuits of the sensor. Such embodiments may be suitable for operation in conditions where access to the sensor is limited or relatively difficult.

In other embodiments, the sensor may communicate with another device, component, system, or circuit, such as a host. FIG. 12 illustrates such an arrangement according to an exemplary embodiment.

Specifically, a sensor, such as the sensors depicted in FIGS. 3 and 6-9, includes a controller, such as MCU 310. Circuit arrangement 600 in FIG. 12 also includes a host (or device or component or system or circuit) 605. The sensor, specifically, the controller (MCU 310) communicates with host 605 via link 370.

In exemplary embodiments, link 370 may include a number of conductors, and facilitate performing a number of functions. In some embodiments, link 370 may constitute a multi-conductor cable or other or similar means of coupling. In some embodiments, link 370 may constitute a bus.

In some embodiments, link 370 may constitute a wireless link (e.g., the sensor and host 605 include receiver, transmitter, or transceiver circuitry that allow wireless communication via link 370 by using radio-frequency (RF) signals). Use of a wireless link provides the advantage of communication without using cumbersome electrical connections, and may allow arbitrary or desired locations for the sensor and host 605.

In some embodiments, link 370 may constitute an optical link. Use of an optical link allows for relatively low noise in link 370. In such a situation, the sensor and host 605 may include optical sources and/or receivers or detectors, depending on whether unidirectional or bidirectional communication is desired.

In some embodiments, link 370 provides a mechanism for supplying power to various parts of the sensor. The sensor may include one or more local regulators, as desired, to regulate or convert the power received from host 605 (or other source), for example, by changing the voltage level or increasing the load regulation, as desired.

In some embodiments, link 370 provides a mechanism for the sensor and host 605 to communicate a variety of signals. Examples include data signals, control signals, status signals, and handshaking signals (e.g., as used in information exchange protocols). As an example, link 370 provides a flexible mechanism by which the sensor may receive information (e.g., calibration information) from host 605.

As another example, the sensor may provide information, such as data corresponding to or derived from a stimulus applied to the sensors. Examples of such data include information regarding displacement, velocity, and/or acceleration. Using this mechanism, host 605 may record a log of the data using desired intervals.

In exemplary embodiments, link 370 provides a flexible communication channel by supporting a variety of types of signals, as desired. For example, in some embodiments, link 370 may be used to communicate analog signals. In other embodiments, link 370 may be used to communicate digital signals. In yet other embodiments, link 370 may be used to communicate mixed-signal information (both analog and digital signals).

In some embodiments, host 605 may constitute or comprise an MCU (or other processor or controller) (not shown). In such scenarios, MCU 310 in the sensor may be omitted or may be moved to host 605, as desired. As an alternative, in some embodiments, the MCU in host 605 may communicate with MCU 310 in the sensor.

One aspect of the disclosure relates to sensors with one or more communication ports that may be used to configure (or configure or adjust or vary or trim or change or calibrate) one or more sensor characteristics (or parameters or attributes). By using the communication port, certain circuits or subsystems may be eliminated. Examples of such circuits include external gain amplifiers, external signal conditioners, and the like.

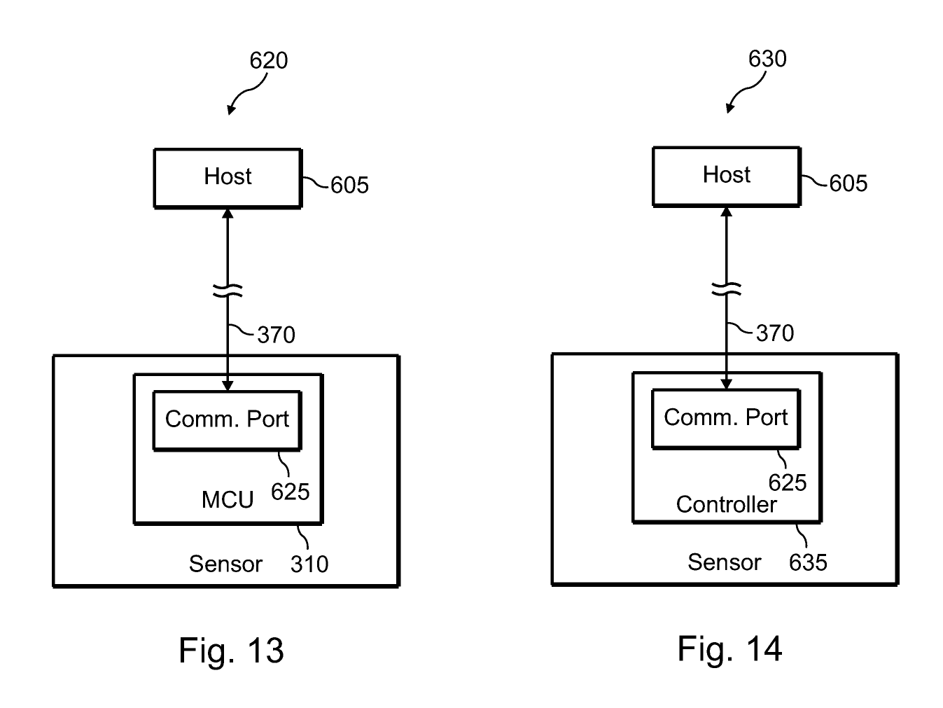

The communication port may be implemented or realized in sensors according to exemplary embodiments in a variety of ways. FIGS. 13-15 illustrate some examples.

FIG. 13 depicts a circuit arrangement 620 for using a communication port in a sensor according to an exemplary embodiment. The circuit arrangement in FIG. 13 is similar to the circuit arrangement shown in FIG. 12. The circuit arrangement in FIG. 13 in addition shows MCU 310 as including a communication port 625 (although, as noted, multiple communication ports 625 may be used, as desired).

Communication port 625 couples to link 370, and provides a mechanism for host 605 and the sensor to communicate information. The information may include data or commands to configure one or more sensor characteristics. In addition, in some embodiments, the information may include the output information of the sensor, for example, output information or data corresponding to one or more stimuli, as described above.

In some embodiments, communication port 625 may use programmable resources of MCU 310, such as port circuitry and associated logic that a user may configure or program. In some embodiments, communication port 625 may use dedicated port or communication circuitry included in MCU 310.

Furthermore, in the embodiment shown, communication port 625 is included as part of MCU 310. In other embodiments, communication port 625 may be included within the sensor, but as a separate circuit from MCU 310.

FIG. 14 illustrates a circuit arrangement 630 for using a communication port in a sensor according to another exemplary embodiment. The circuit arrangement in FIG. 14 is similar to the circuit arrangement shown in FIG. 13. Instead of MCU 310, the circuit arrangement in FIG. 14 uses a controller 635, which includes a communication port 625 (although, as noted, multiple communication ports 625 may be used, as desired).

Referring to FIG. 14, communication port 625 couples to link 370, and provides a mechanism for host 605 and the sensor to communicate information. The information may include data or commands to configure one or more sensor characteristics. In addition, in some embodiments, the information may include the output information of the sensor, for example, output information or data corresponding to one or more stimuli, as described above.

In exemplary embodiments, controller 635 may be realized or implemented using a variety of configurations or architectures. For example, in some embodiments, controller 635 may constitute a finite-state machine. As another example, in some embodiments, controller 635 may include programmable logic circuitry. As yet another example, in some embodiments, controller 635 may include a processor, such as a central processing unit (CPU).

Furthermore, in the embodiment shown, communication port 625 is included as part of controller 635. In other embodiments, communication port 625 may be included within the sensor, but as a separate circuit from controller 635.

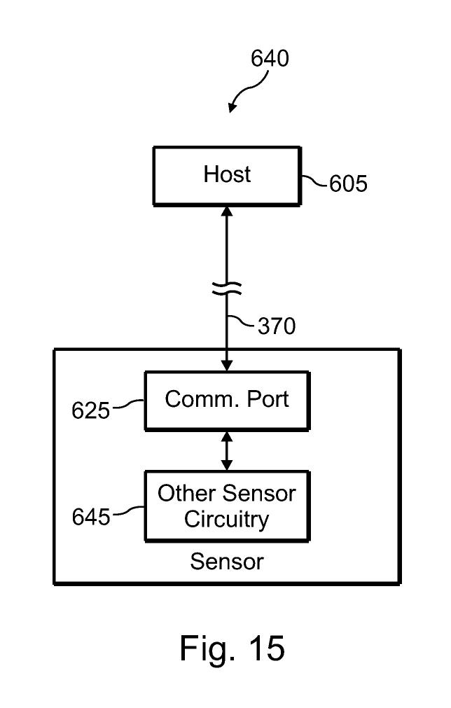

FIG. 15 illustrates a circuit arrangement 640 for using a communication port in a sensor according to another exemplary embodiment. The circuit arrangement in FIG. 15 is similar to the circuit arrangement shown in FIGS. 13-14. Instead of MCU 310 or controller 635, the circuit arrangement in FIG. 15 includes circuitry for realizing or implementing communication port 625 (although, as noted, multiple communication ports 625 may be used, as desired).

Referring to FIG. 15, communication port 625 couples to link 370, and provides a mechanism for host 605 and the sensor to communicate information. The information may include data or commands to configure one or more sensor characteristics. In addition, in some embodiments, the information may include the output information of the sensor, for example, output information or data corresponding to one or more stimuli, as described above.

In exemplary embodiments, communication port 625 may be implemented or realized using a variety of configurations or circuits. For example, communication port 625 may include a receiver (RX) to receive information from host 605 via link 370, a transmitter (TX) to transmit information via link 370, or a transceiver to both receive and transmit information via link 370.

As another example, communication port 625 may include universal asynchronous receiver transmitter (UART) circuitry, as desired. Other possibilities exist and are contemplated, as persons of ordinary skill in the art will understand.

In some embodiments, communication port 625 may provide unidirectional communication or flow of data (e.g., from host 605 to the sensor, or vice-versa). For example, through a unidirectional communication port 625, host 605 may send commands or information to the sensor in order to configure one or more characteristics of the sensor.

In some embodiments, communication port 625 may provide bidirectional communication between host 605 and the sensor. For example, through a bidirectional communication port 625, host 605 may send commands or information to the sensor in order to configure one or more characteristics of the sensor. In addition, using bidirectional communication port 625, the sensor may provide information (e.g., output data of the sensor) to host 605, as described above.

In exemplary embodiments, communication port 625 may provide simplex, half-duplex, or full-duplex communication. For example, in some embodiments, communication port 625 allows simplex communication, that is from the sensor to host 605, or from host 605 to the sensor, but not both.

As another example, in some embodiments, communication port 625 allows half-duplex communication. In this arrangement, communication may occur from the senor to host 605 or vice-versa, but in one direction at a given time. As another example, in some embodiments, communication port 625 allows full-duplex communication. In this arrangement, communication may occur from the senor to host 605 or vice-versa simultaneously.

In exemplary embodiments, communication port 625 may have a variety of configurations. For example, in some embodiments, communication port 625 may constitute a serial communication port. Serial communication ports use relatively few conductors (as part of link 370) to communicate information but, depending on other parameters (e.g., clock or baud rate), might have slower communication speeds than other types of communication port.

As another example, communication port 625 may constitute a parallel communication port. Parallel communication ports use relatively few conductors (as part of link 370) to communicate information but, depending on other parameters, might have faster communication speeds than other types of communication port (e.g., a serial communication port).

Furthermore, in exemplary embodiments, communication port 625 may use a synchronous or an asynchronous signaling scheme. In some embodiments, communication port 625 uses a synchronous signaling scheme. In such arrangements, communication of information is synchronized to one or more signals, such as timing or clock signals (whether from host 605 or the sensor).

In some embodiments, communication port 625 uses an asynchronous signaling scheme. In such arrangements, communication of information is not synchronized to a timing or clock signal, but other timing arrangements are made. Examples include communication ports that can communication according to the RS-232, RS-485, etc.

In exemplary embodiments that use serial communication, a variety of types of serial port, bus, interface, and/or protocols may be used. Examples include interfaces or ports operating according to protocols such as RS-232, RS-485, and the like, as mentioned above. Other examples serial port, bus, interface, circuitry, and/or associated protocols such as inter-integrated circuit (I²C), for instance, using serial data line (SDA) and serial clock line (SCL) signals; serial peripheral interface (SPI), for example, using serial clock (SCLK), master-output, slave input (MOST), master input-slave output (MISO), and slave select (SS) signals; two-wire serial communication; system management bus (SMB or SMBus); and the like.

A variety of sensor characteristics may be configured in exemplary embodiments. More specifically, one or more communication ports 625 may be used to configure one or more sensor characteristics.

For example, FIG. 8 includes variable resistors 305A-305B that allow configuring the gains of TIAs 118A-118B, respectively, and thus the dynamic range, overload point, or the peak overload point of the sensor. Furthermore, FIG. 8 includes variable resistors 320A-320B that allow configuring the coil constant or full-scale range of the sensor.

As another example, FIG. 9 includes variable resistor 305 to allow configuring the gain of TIA 118 and, thus the dynamic range, overload point, or the peak overload point of the sensor. In addition, FIG. 9 includes FIG. 9 includes variable resistors 320A-320B that allow configuring the coil constant or full-scale range of the sensor. FIG. 9 also includes variable resistors 340 and 360 that allow configuring the gains of amplifiers 345 and 355 of the sensor, respectively, as discussed above. As yet another example, parameters or characteristics relating to the sleep and normal modes of operation of the sensor (e.g., which blocks are powered down in the sleep mode, etc.), described above, may be configured using communication port(s) 625.

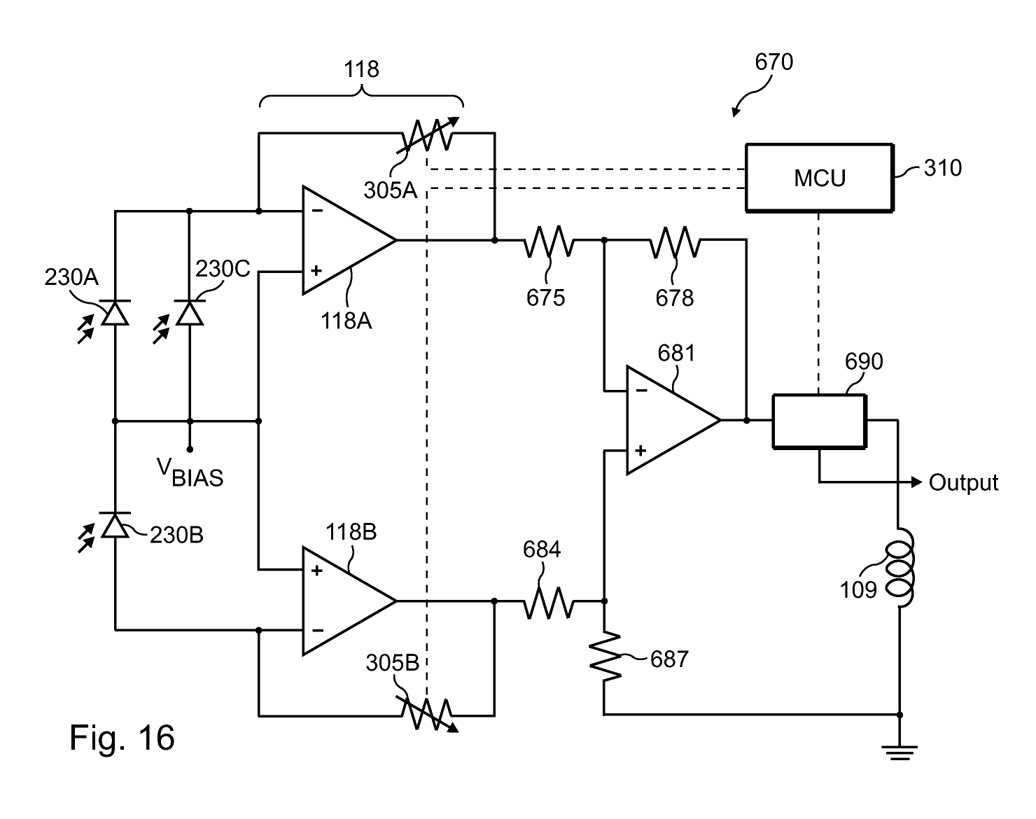

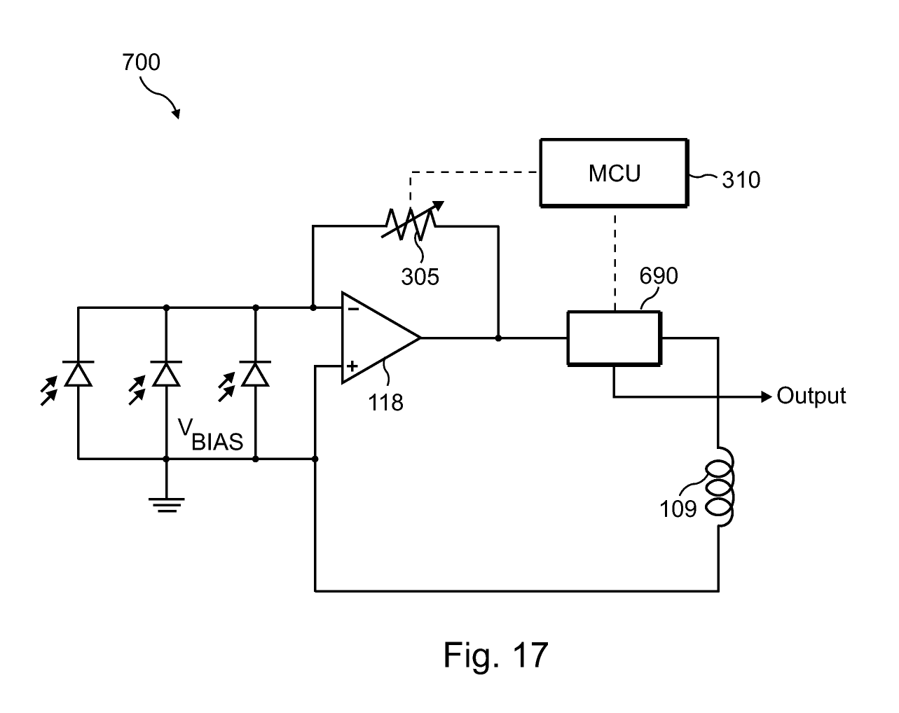

FIGS. 16-17 provide additional examples of configuring sensor characteristics by using communication port(s) 625. In the examples shown, MCU 310 use communication port(s) 625 (not shown in FIGS. 16-17) to configure the sensor characteristics. Referring to FIG. 16, the figure a schematic diagram or circuit arrangement 670 for a sensor according to an exemplary embodiment, for instance sensors 200 and 250 in FIGS. 6 and 7, respectively.

Referring to FIG. 16, as described above, optical detectors 230A-230C (photodiodes in the embodiment shown) provide an output signal to TIA 118. A bias source, labeled V_{BIAS}, for example, ground or zero potential, provides an appropriate bias signal to detectors 230A-230C. The output signal of optical detectors 230A-230C is provided to TIA 118 (including TIAs 118A-118B) as a differential signal.

Note that FIG. 16 omits light source 225 for the sake of clarity of presentation. Light source 225, e.g., a VCSEL, may be powered by an appropriate circuit (not shown). Examples include a voltage regulator, a reference source, etc., as desired. Also, in some embodiments, MCU 310 may control or program the light level that light source 225 emits, depending on various factors, such as power consumption, desired sensor parameters and performance, etc.

In the embodiment shown in FIG. 16, TIA 118 includes two individual TIA circuits or amplifiers, 118A and 118B, to accommodate the differential input signal. TIA 118 includes resistors 305A-305B that allow configuring the respective gains of TIAs 118A-118B.

By adjusting resistor 305A, the gain of amplifier 118A may be adjusted. Similarly, by adjusting resistor 305B, the gain of amplifier 118B may be adjusted. A controller, such as a microcontroller unit (MCU) 310 in the exemplary embodiment shown, adjusts the values of resistors 305A-305B. By adjusting resistors 305A-305B, the dynamic range, overload point, or the peak overload point of the sensor may be configured.

As noted above, MCU 310 may typically adjust resistors 305A-305B to the same resistance value. In some situations, however, resistors 305A-305B might be adjusted to different values, as noted above.

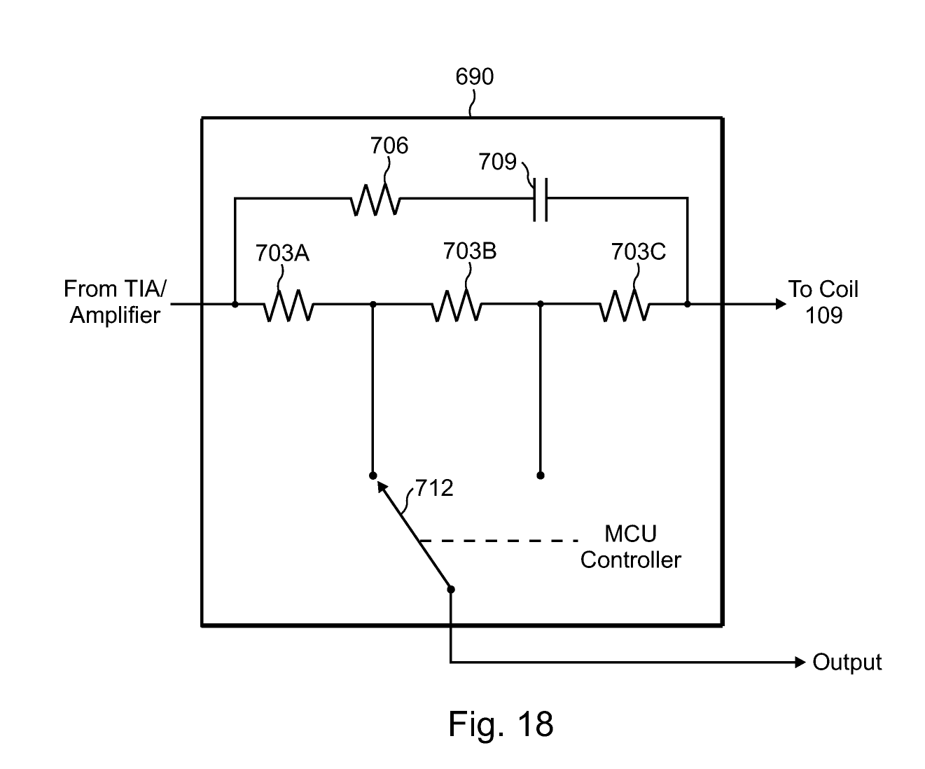

The outputs of amplifiers 118A-118B drive the inputs of amplifier 681 via a resistor network that includes resistors 675, 678, 684, and 687. The output of amplifier 681 drives a feedback network 690. In exemplary embodiments, such as the embodiment of FIG. 18, feedback network 690 includes a resistive or resistive-capacitive network. In other embodiments, other types of network or circuitry may be used in feedback network 690. Regardless of the particular implementation of feedback network 690 in a given application, MCU 310 can configure feedback network 690 and, thus, one or more characteristics of the sensor.

Referring again to FIG. 16, feedback network 690 drives coil 109. Feedback network 690 also provides the output signal of the sensor. In exemplary embodiments, feedback network 690, similar to resistors 320A-320B in FIGS. 8-9, allows configuring the coil constant and full-scale range of the sensor.

In the embodiment shown, MCU 310, in cooperation with communication port(s) 625 (not shown), configures feedback network 690 in order to configure one or more characteristics of the sensor, such as scale factor or full-scale range of the sensor. In other embodiments, such as the exemplary embodiments shown in FIGS. 13-15, other arrangements may be used (e.g., a controller, communication port circuitry, etc.), as desired.

FIG. 17 illustrates the figure a schematic diagram or circuit arrangement 700 for a sensor according to an exemplary embodiment, for instance sensors 200 and 250 in FIGS. 6 and 7, respectively. Referring to FIG. 17, as described above, optical detectors 230A-230C (photodiodes in the embodiment shown) provide an output signal to TIA 118. A bias source (V_{BIAS}), ground in the example shown, provides an appropriate bias signal to detectors 230A-230C. The output signal of optical detectors 230A-230C is provided to TIA 118.

Note that FIG. 17 omits light source 225 for the sake of clarity of presentation. Light source 225, e.g., a VCSEL, may be powered by an appropriate circuit (not shown). Examples include a voltage regulator, a reference source, etc., as desired. Also, in some embodiments, MCU 310 may control or program the light level that light source 225 emits, depending on various factors, such as power consumption, desired sensor parameters and performance, etc.

By adjusting resistor 305, the gain of TIA 118 may be adjusted. A controller, such as a microcontroller unit (MCU) 310 in the exemplary embodiment shown, adjusts the values of resistor 305. By adjusting resistor 305, the dynamic range, overload point, or the peak overload point of the sensor may be configured.

The output of TIA 118 drives feedback network 690. As noted above, feedback network 690 may include a resistive or resistive-capacitive network or other types of network or circuitry, as desired. Regardless of the particular implementation of feedback network 690 in a given application, MCU 310 can configure feedback network 690 and, thus, one or more characteristics of the sensor.

Feedback network 690 drives coil 109. Feedback network 690 also provides the output signal of the sensor. In exemplary embodiments, feedback network 690, similar to resistors 320A-320B in FIGS. 8-9, allows configuring the coil constant and full-scale range of the sensor.

In the embodiment shown in FIG. 17, MCU 310, in cooperation with communication port(s) 625 (not shown), configures feedback network 690 in order to configure one or more characteristics of the sensor, such as scale factor or full-scale range of the sensor. In other embodiments, such as shown in FIGS. 13-15, other arrangements may be used (e.g., a controller, communication port circuitry, etc.), as desired.

FIG. 18 depicts a feedback network 690 for configuring one or more sensor characteristics according to an exemplary embodiment. In the example shown, feedback network 690 includes a string or cascade of three resistors or resistance sections 703A-703C. Resistors 703A-703C are coupled between the input (labeled “From TIA/amplifier”) and output of feedback network 690 (labeled “Output”). Although the example in the figure shows three resistors, in general other numbers of resistors may be used, as desired. Generally speaking, N resistors may be used in various embodiments, where N denotes a positive integer greater than one.

In addition, feedback network 690 optionally includes resistor 706 and capacitor 709. Resistor 706 and capacitor 709 constitute a phase-compensation network to assure adequate stability (e.g., phase margin) for closed-loop sensors. Note that resistor 706 and capacitor 709 do not set the scale factor in the frequency band of interest (e.g., the frequency band within which the sensor is designed to respond to a stimulus).

Feedback network 690 further includes a switch 712, coupled to resistors 703A-703C. Switch 712 has a number of positions that are coupled to corresponding nodes or taps in the cascade-coupled resistors 703A-703C. For example, the left position of switch 712 couples to the node between resistor 703A and resistor 703B. As another example, the right position of switch 712 couples to the node between resistor 703B and resistor 703C, and so on, depending on the number of resistors and switch positions.

The wiper (or common node or terminal) of switch 712 selectively couples the various positions to the output of feedback network 690. Depending on the position of the wiper of switch 712, a corresponding number of resistors and, hence, a total amount of resistance, is provided between the input and output of feedback network 690. Thus, by changing the position of the wiper of switch 712, the effective resistance of the resistor coupled between the input and output of feedback network 690 and, thus, the full-scale range or coil constant of the sensor, may be configured.

Note that although switch 712 has two positions in the example shown, other switch configurations may be used. For example, if the number of resistors is increased (e.g., if N resistors are used, as described above), a switch with corresponding number of positions (e.g., N−1) may be used.

The choice of the number of positions of switch 712 and the number of resistors, i.e., N, affects the granularity with which the value of the effective resistor between the input and output of feedback network 690 may be configured. A tradeoff exists between that level of granularity and the complexity of the circuit.

The appropriate number of switch positions of switch 712 and resistors depends on factors such as desired performance specifications (e.g., the number of gain profiles), cost, complexity, space constraints, etc., as persons of ordinary skill in the art will understand. For example, by using a larger number of resistors and corresponding positions of switch 712, a correspondingly larger number of resistor values may be configured. As a consequence, a larger number of gain, range, coil constant, etc. values may be configured. For example, in some embodiments, by using communication port(s) 625, a desired gain, range, coil constant, etc., may be selected from a plurality or set of available values (e.g., the resistance values available as a result of selecting the position of switch 712).

In some embodiments, the resistance of resistors 703A-703N is equal or nearly equal, say, R ohms. In this situation, changing the wiper position of switch 712 changes the effective resistance value by R, i.e., uniform resistance-change steps. In other embodiments, different resistance values may be used for resistors 703A-703N. By using unequal resistance values, non-uniform resistance-change steps may be implemented, for instance in situations where relatively large changes in gain are desired.

In the embodiments shown, MCU 310 controls switch 712 and various resistors, for instance, in FIGS. 8-9 and 16-17. Other arrangements, however, are contemplated and may be used. For example, a controller, either in the sensor or in a remote location (e.g., a remote host) may control switch 712. As another example, switch 712 may be manually controlled by a user, e.g., by setting switch 825 to the desired position. As another example, switch 712 may be controlled by a memory.

Furthermore, in exemplary embodiments, switch 712 may be implemented in a number of ways. For example, in some embodiments, switch 712 may be implemented electronically. As another example, in some embodiments, switch 712 may be implemented mechanically. As another example, in some embodiments, switch 712 may be implemented as a combination of the two, i.e., electromechanically.

Other examples of sensor characteristics that may be configured using one or more communication ports 625 are described in detail in related applications cited above and incorporated by reference. Such characteristics include configuring the power consumption of sensor (e.g., duty cycle and/or pulse-repetition rate of light source 225, control of sleep mode parameters or characteristics), the configuration of coil 109 (e.g., number of coils or coil sections and/or the topology of coil 109), the configuration of coil damping or braking (e.g., turning on or off a depletion-mode field-effect transistor (FET) to damp or brake coil 109), etc.

By using communication port(s) 625, resistors, switch positions, transistor states, duty cycles, sleep mode circuitry, and/or coils/coil sections, etc., may be configured in various embodiments. Consequently, one or more characteristics of sensors may be configured, as desired.

As noted above, communication port(s) 625 may be used to provide information, such as data or output signal of the sensor, to another circuit or subsystem, such as host 605. In some embodiments, host 605 may process information received from the sensor, and use the results of the processing to configure one or more characteristics of the sensor.

For example, host 605 may monitor the output signal of the sensor via communication port 625. Depending on the values of the output signal of the sensor, host 605 may configure one or more characteristics of the sensor. In other words, host 605 may control the operation and characteristics of the sensor.

For example, in some embodiments, host 605 may monitor the peak value of the output signal of the sensor. If the peak value exceeds a certain quantity, e.g., a threshold or pre-determined or specified value, host 605 may configure various characteristics of the sensor, such as the characteristics described above. For instance, host 605 may configure the gain, full-scale range, coil constant, and peak overload point of the sensor. Other arrangements are contemplated and are possible in various embodiments.

In exemplary embodiments, the configured characteristics of the sensor may be retained, as desired. For example, in some embodiments, the configuration of the sensor (e.g., the position of switch 712 in feedback network 690) may be retained in a volatile memory, such as random access memory (RAM). In this situation, the configuration of the sensor remains available and valid while power is applied to the memory. Once power is removed from the memory, the configuration changes, for example, by returning to a default configuration.

As another example, in some embodiments, the configuration of the sensor (e.g., the position of switch 712 in feedback network 690) may be retained in a non-volatile memory, such as read-only memory (ROM), electrically erasable programmable ROM (EEPROM), or flash memory. In this situation, the configuration of the sensor remains available and valid even if power is removed from the memory (e.g., after a sensor has been configured during manufacturing, or before deployment in the field, or after calibration, etc.). By virtue of using a non-volatile memory, even after power is removed from the memory (e.g., during the sleep state), the sensor's configuration is retained.

Although sensors according to exemplary embodiments have been described and illustrated in the accompanying drawings, a variety of other embodiments and arrangements are contemplated. The following description provides some examples.

In some embodiments, MCU 310 may be omitted. Instead, a remote host, device, component, system, circuit, etc., may couple to circuitry in the sensor to perform various operations, e.g., adjust the values of the various resistors. The sensor may include circuitry to facilitate communication with the remote host. Analog, digital, or mixed-signal control communication signals may be used to adjust the resistor values, as desired.

In some embodiments, the electrical components (e.g., MCU 310, TIA 118, etc.) and rest of the sensor components (e.g., coil, optical position sensor) reside in the same housing. In other embodiments, the electrical components and rest of the sensor components reside in different components (e.g., to allow easier access to some components, while protecting other components) of the same housing.

In yet other embodiments, the electrical components and rest of the sensor components, for example, the coil and/or optical position sensor, reside in different or separate housings. The choice of configuration depends on a variety of factors, as persons of ordinary skill in the art will understand. Examples of such factors include design and performance specifications, the intended physical environment of the sensor, the level of access desired to various components, cost, complexity, etc.

Sensors according to exemplary embodiments may be used in a variety of applications. For example, sensors according to some embodiments may be used for geological exploration. As another example, sensors according to some embodiments may be used for detecting seismic movement, i.e., in seismology. As another example, sensors according to some embodiments may be used for detecting and/or deriving various quantities related to navigation, i.e., in inertial navigations. Other applications include using the sensor as a reference sensor for motion stimulus testing of other components or sensors under test.

Referring to the figures, persons of ordinary skill in the art will note that the various blocks shown might depict mainly the conceptual functions and signal flow. The actual circuit implementation might or might not contain separately identifiable hardware for the various functional blocks and might or might not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation. Other modifications and alternative embodiments in addition to those described here will be apparent to persons of ordinary skill in the art. Accordingly, this description teaches those skilled in the art the manner of carrying out the disclosed concepts, and is to be construed as illustrative only. Where applicable, the figures might or might not be drawn to scale, as persons of ordinary skill in the art will understand.

The forms and embodiments shown and described should be taken as illustrative embodiments. Persons skilled in the art may make various changes in the shape, size and arrangement of parts without departing from the scope of the disclosed concepts in this document. For example, persons skilled in the art may substitute equivalent elements for the elements illustrated and described here. Moreover, persons skilled in the art may use certain features of the disclosed concepts independently of the use of other features, without departing from the scope of the disclosed concepts.

1. A sensor, comprising:
a coil suspended in a magnetic field;
an optical detector to detect displacement of the coil in response to a stimulus;
a feedback circuit coupled to the optical detector and to the coil; and
a serial communication port used to configure at least one characteristic of the sensor, wherein the at least one characteristic of the sensor comprises an overload point of the sensor, a gain of the sensor, a full-scale range of the sensor, a power consumption of sensor, sleep mode parameters of the sensor, a coil configuration of the sensor, and/or coil damping of the sensor.

2. The sensor according to claim 1, wherein the serial communication port resides in a microcontroller unit (MCU).

3. The sensor according to claim 1, wherein the serial communication port resides in controller.

4. The sensor according to claim 1, wherein the serial communication port is further used to provide output information of the sensor to a host.

5. The sensor according to claim 4, wherein depending on the output information of the sensor, the host uses the serial communication port to configure the at least one characteristic of the sensor.

6. The sensor according to claim 5, wherein the host uses the serial communication port to configure the at least one characteristic of the sensor by monitoring peak value of the output information of the sensor.

7. The sensor according to claim 1, wherein the feedback circuit comprises a feedback network, and wherein the feedback network is configured in order to configure the at least one characteristic of the sensor.

8. The sensor according to claim 7, wherein the feedback network is configured by changing a position of a switch.

9. The sensor according to claim 1, wherein the feedback circuit comprises at least one variable resistor, and wherein the at least one variable resistor is configured in order to configure the at least one characteristic of the sensor.

10. The sensor according to claim 1, wherein the serial communication port used to configure at least one characteristic of the sensor to generate a sensor configuration, and wherein the sensor configuration is stored in a volatile memory.

11. The sensor according to claim 1, wherein the serial communication port used to configure at least one characteristic of the sensor to generate a sensor configuration, and wherein the sensor configuration is stored in a non-volatile memory.

12. A system, comprising:
a sensor, comprising:
a coil suspended in a magnetic field;
an optical detector to detect displacement of the coil in response to a stimulus;
a feedback circuit coupled to the optical detector and to the coil; and
a microcontroller unit (MCU) comprising a serial communication port used to receive information to configure at least one characteristic of the sensor, the serial port further used to provide output information of the sensor,
wherein the at least one characteristic of the sensor comprises an overload point of the sensor, a gain of the sensor, a full-scale range of the sensor, a power consumption of sensor, sleep mode parameters of the sensor, a coil configuration of the sensor, and/or coil damping of the sensor.

13. The system according to claim 12, further comprising a host coupled to the serial communication port to receive the output information of the sensor.

14. The system according to claim 13, wherein the host monitors the output information of the sensor to detect a peak value, and wherein depending on the peak value, the host uses the serial communication port to configure the at least one characteristic of the sensor.

15. The system according to claim 12, wherein the serial communication port comprises inter-integrated circuit (I²C) circuitry or serial peripheral interface (SPI) circuitry.

16. The system according to claim 12, wherein the serial communication port operates asynchronously.

17. A method of operating a sensor, the sensor including a coil suspended in a magnetic field, an optical detector to detect displacement of the coil in response to a stimulus, a feedback circuit coupled to the optical detector and to the coil, and a serial communication port, the method comprising using the serial communication port to configure at least one characteristic of the sensor, wherein the at least one characteristic of the sensor comprises an overload point of the sensor, a gain of the sensor, a full-scale range of the sensor, a power consumption of sensor, sleep mode parameters of the sensor, a coil configuration of the sensor, and/or coil damping of the sensor.

18. The method according to claim 17, further comprising using the serial communication port to provide output information of the sensor to a host.

19. The method according to claim 18, wherein using the serial communication port to configure at least one characteristic of the sensor further comprises the host using the serial communication port to configure the at least one characteristic of the sensor depending on the output information of the sensor.

20. The method according to claim 17, wherein using the serial communication port to configure at least one characteristic of the sensor comprises using the serial communication port to cause a change in a resistor value or a change in a position of a switch in the sensor.
